(19) United States
(12) Patent Application Publication
(10) Pub. No.: US 2012/0274342 A1
(43) Pub. Date: Nov. 1, 2012

(54) TRAUMA DETECTION SYSTEM

(76) Inventor: Jason Achord, Blossom, TX (US)

(21) Appl. No.: 13/096,213

(22) Filed: Apr. 28, 2011

(51) Int. Cl. G01N 27/04; G01R 27/08

(52) U.S. Cl. 324/693

(57) ABSTRACT

A trauma detecting body wear apparatus that may be configured with an outer conductive layer, and a medium layer proximate to the outer conductive layer. The medium layer may include an insulating material configured to prevent current flow to the outer layer. There may be an inner conductive layer configured with a penetration-resistant material, and the inner layer may also be configured with a conductive coating treatment, and may be further connected to an energized power source. The body wear apparatus may also include a transmitter configured to transmit a signal when current flows from the energized power source to the outer conductive layer.

### BACKGROUND OF THE DISCLOSURE

1. Field of the Disclosure

Embodiments disclosed herein relate generally to trauma detection systems useable to determine, or otherwise indicate, an impact, penetration, or other form of trauma detected by the system. Further embodiments relate to protective body wear, including bullet-proof vests and other protective gear, which use electrical circuits and devices incorporated within the body wear to detect and indicate trauma. In particular, the protective body gear may be configured to detect physical external trauma experienced by the wearer, and transmit a signal to a receiver.

2. Background

Physical trauma may come in many forms, such as a penetrating bullet fired from a firearm, a stabbing from a weapon such as a knife, an electrified taser, a piercing arrow launched with a bow, high-velocity shrapnel from an explosion, and more. There are a number of conventional ways to protect against, and even detect, such traumas.

A bullet proof vest, for example, protects a wearer against a variety of sources of trauma. In many cases, wearing one is effective prevention against bodily injuries that would otherwise be life threatening if not for the vest. However, in other less fortunate cases, the vest may only partially prevent or reduce serious injury. In such instances, it might be difficult or even impossible for the wearer to communicate vital information, as these injuries might prevent the wearer from doing so.

The previous technology required to implement such systems is complex, expensive, and unreliable. For example, some devices utilize one or more grids of electrical wires in order to detect and locate trauma to a person. The use of this technology requires construction and application of multiple wires and multiple layers of wires to the existing outerwear. By doing so, the total weight and thickness of the outerwear is significantly increased. An additional problem with this design is that it requires a large battery pack and/or frequent maintenance to change or charge the batteries.

Other devices use a piezoelectric layer to create an electrical signal when physical impact occurs on armored vehicles. Piezoelectric material creates a voltage difference as physical force is applied to it, and is heavy, stiff, and expensive. Applying such technology to protective outerwear is problematic as it will significantly increase the weight of such outerwear and limit the mobility of the wearer.

What is needed is a trauma detection system wearable with protective outerwear, such as a bullet proof vest, which upon detecting trauma, will automatically transmit a pre-determined signal, alert, or information that the wearer has been injured or that a physical trauma of some kind has occurred. Such trauma detecting outerwear may be utilized in a number of applications.

What is further needed is trauma detection system that is portable, where the number, the size, and the weight of the required components are minimal, thus adding the least amount to the overall size and weight of the protective outerwear. What is also needed is a trauma detection system that is flexible and comfortable to the wearer, allowing the freedom to move with the same ease as if no such detection system was present.

It is desirable that a trauma detection system have the ability to sense trauma caused by different types of weapons, such as bullets, knives, arrows, tasers, shrapnel and other sharp objects. It is also desirable that the detection system be inexpensive and affordable, whereby low-profit or non-profit agencies, such as government agencies, police force, etc., can purchase a greater number of units, thus protecting a greater number of individuals. Lastly, it is desirable to provide a detection system that is highly reliable, needing to perform in the most hostile whether and in multitude of environments.

### SUMMARY

Embodiments disclosed herein may provide for an trauma detection system that may include a section of body armor configured with a first layer, a second layer disposed proximate to the first layer, and an insulator medium positioned between the first layer and the second layer. The detection system may also include a transmitter device, and a power source in powered connection with the transmitter device, and also configured to supply power to the transmitter device. The first layer may be operatively connected to the power source, and the second layer may be operatively connected to the transmitter device. The transmitter device may be configured to transmit a trauma signal when the first layer and the insulating medium are penetrated by an external conductive element and also at least partially contacts the second layer.

Other embodiments disclosed herein may provide for a trauma detecting body wear apparatus that may be configured with an outer conductive layer, and a medium layer proximate to the outer conductive layer. The medium layer may include an insulating material configured to prevent current flow to the outer layer. There may be an inner conductive layer configured with a penetration-resistant material, and the inner layer may also be configured with a conductive coating treatment, and may be further connected to an energized power source. The body wear apparatus may also include a transmitter configured to transmit a signal when current flows from the energized power source to the outer conductive layer.

Yet other embodiments disclosed herein may relate to a method for detecting trauma that may include the steps of using a section of body armor, transmitting a signal that pertains to a detected trauma by contacting a first layer of material with a second layer of material. The body armor may include the first layer, the second layer disposed proximate to the first layer, and an insulator medium positioned between the first layer and the second layer. The body armor may also include a transmitter device, and a power source in powered connection with the transmitter device, and also configured to supply power to the transmitter device.

The method may include additional steps of having first responders respond to the transmitted signal. In addition, the first layer and the second layer may be configured to contact each other upon at least one of an impact of the first layer, a penetration of the first layer, and combinations thereof.

The power source may be an electrical power source, whereby the electrical power source may include a first terminal in electrical connection with the first layer, and a second terminal in electrical connection with the transmitter device.

Other aspects and advantages of the disclosure will be apparent from the following description and the appended claims.

### BRIEF DESCRIPTION OF DRAWINGS

A full understanding of embodiments disclosed herein is obtained from the detailed description of the disclosure presented herein below, and the accompanying drawings, which are given by way of illustration only and are not intended to be limitative of the present embodiments, and wherein:

FIGS. 1A, 1B, 1C, and 1D show up-close, cross-sectional profile views of various trauma detection apparatuses configured with multiple layers, in accordance with embodiments of the present disclosure.

FIG. 2 shows a cross-sectional isometric view of a layered trauma detection system configured with an electrical circuit, in accordance with embodiments of the present disclosure.

FIGS. 3A and 3B show various schematic views of an inertial position switch usable with a trauma detection system, in accordance with embodiments of the present disclosure.

FIGS. 4A and 4B show various views of a user configured with a trauma detection system, in accordance with embodiments of the present disclosure.

### DETAILED DESCRIPTION

Specific embodiments of the present disclosure will now be described in detail with reference to the accompanying Figures. Like elements in the various figures may be denoted by like reference numerals for consistency. Further, in the following detailed description of embodiments of the present disclosure, numerous specific details are set forth in order to provide a more thorough understanding of the disclosure. However, it will be apparent to one of ordinary skill in the art that the embodiments disclosed herein may be practiced without these specific details. In other instances, well-known features have not been described in detail to avoid unnecessarily complicating the description.

In addition, directional terms, such as “above,” “below,” “upper,” “lower,” “front,” “back,” etc., are used for convenience in referring to the accompanying drawings. As such, these indicator words refer to general direction and/or orientation, and are only intended for illustrative purposes only, and the terms are not meant to limit the disclosure.

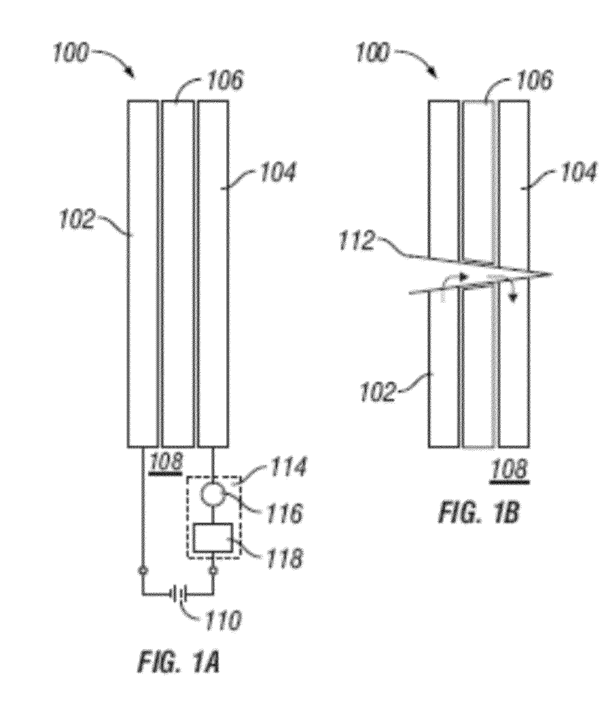

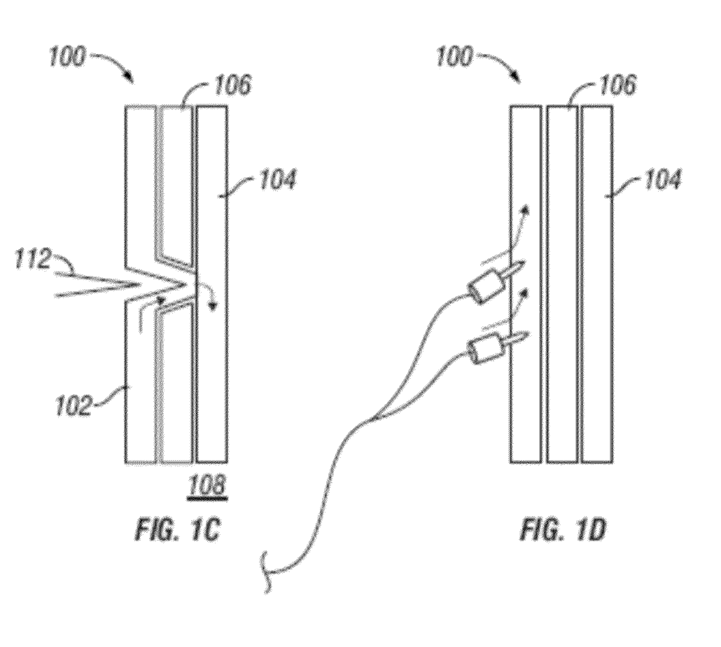

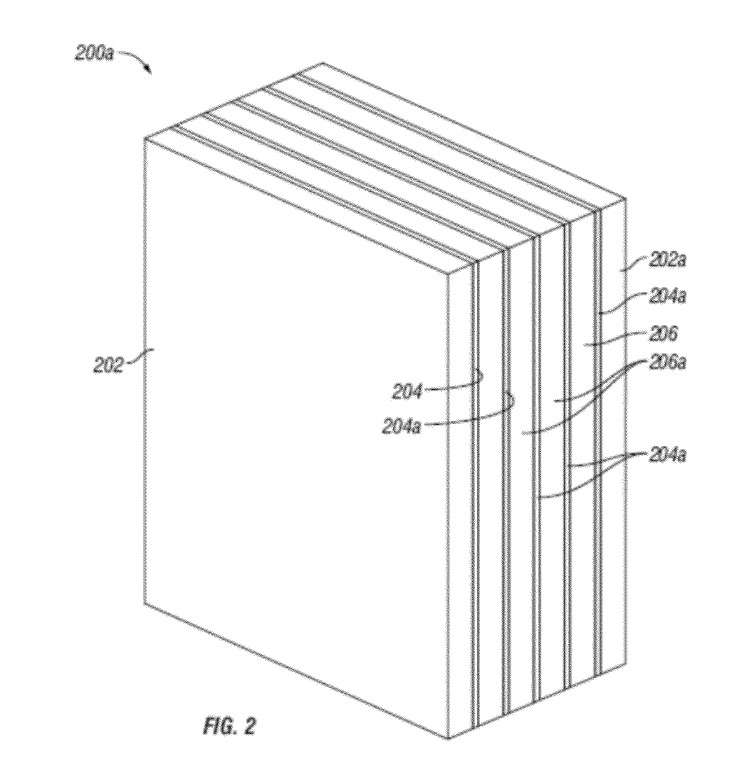

Referring now to FIG. 1A, a close-up, cross-sectional view of a trauma detection system configuration according to embodiments disclosed herein, is shown. FIG. 1A illustrates the general arrangement of a trauma detection system 100 in a first circuit state 101, which may be described as an “open” electrical circuit. As shown, the trauma detection system 100 may include a first conductive layer 102, and a second conductive layer 104. In an embodiment, the layers 102 and/or 104 may be electrically conductive. There may be an intermediary layer 106, which may be an insulator medium, disposed therebetween. In an embodiment, the layer 106 may be electrically non-conductive. There may be a power source 110, an inertia switch 118, and a transmitter device 116 associated therewith.

In operation, the trauma detection system 100 may function by having two layers of conductive material introduced to a body wear apparatus (not shown). The intermediary layer 106 may be configured to keep the conductive layers 102 & 104 from direct contact with each other. The first layer 102 may be connected to the negative terminal of the power source 110 and the first lead of the inertia switch 118. The second layer 104 may be connected to the first lead of the transmitter device 116 and the second lead of the inertia switch 118. The first lead of the transmitter device 116 may be connected to the second layer 104 and the second lead of the inertia switch 118.

The second lead of the transmitter device may be connected to the positive terminal of the power source 110. The first lead of the inertial switch 118 may be connected to both the first layer 102 and the negative terminal of the power source 110, while the second lead of the inertial switch 118 may be connected to both the second layer 104 and the first lead of the transmitter device 118. Accordingly, embodiments disclosed herein may include the transmitter device 116 connected in series with both the inertial switch 118 and layers 102 & 104. In other embodiments, the inertial switch 118 and layers 102 & 104 may be connected in parallel to one another.

The first layer 102 may be an outer layer that is conductive. In one aspect of operation or use, the layer 102 may be conductive, but not electrified. In this manner, the layer 102 may be an effective “negative” terminal. The intermediary layer 106 may be an insulating layer configured to prevent current flow through the layer(s) 102, 104. The second layer 104 may be configured with penetration-resistant material, such as KEVLAR, that may be further “treated” to be conductive. In an embodiment, layer 104 may be electrified/energized, and in effect, functions as a “positive” terminal.

The layers 102, 104, 106 may be configured to operate as a functional switch for the transmitter or alarm. For example, during normal operating conditions the “switch” is in the open position 101. Once the body wear apparatus is penetrated by a metal object, such as a bullet or a knife, the circuit may be completed and the switch is then in a “closed” position 103.

Some applications, such as a law enforcement application, may require the use of a transmitter. In the closed position 103, power may be applied to the transmitter 116, whereby a signal may be generated and, for example, transmitted to a communication device such as a radio in a patrol car (not shown). Alternatively, power may also be applied to the transmitter device 116, when the inertia switch 118 is triggered by a sudden change in motion, indicating a substantial impact. Subsequently, the transmitter device 116 device may simply relay the signal from the transmitter device 116 or send a prerecorded message to department communication personnel or dispatch (not shown). The communication device may have the receiver and sound storage device built into it. There could also be separate device that consist of a receiver and sound storage device that attaches to an existing radio.

The first layer 102 and/or second layer 104 may be made or manufactured from a number of electrically conductive materials. In one embodiment, the conductive material may include a textile where individual fibers within a fabric or yarn are completely and uniformly coated with an inherently electrical conducting polymer.

In forming the layers, one or more of the layers may be coated with a conductive material such as a doped polypyrrole polymer or metallic coating such as silver/nickel/copper like that found in EMI/RF shielding fabrics. Coating in this manner makes a less complicated assembly procedure and reducing chances for failure and false alarms, as compared to conventional technology, such as piezoelectric sensors For example, in order to be sensitive enough to detect a low velocity sharp object impact, the piezo sensor would would be too sensitive and could be set off by unintended bumps and jars.

Textiles, such as those provided by EeonTex, may include individual fibers within a fabric or yarn are completely and uniformly coated with doped polypyrrole (PPY), an inherently conducting polymer. Almost all fabrics—woven, knitted, and nonwoven—and textured and spun yarns—synthetic or natural—can be coated using the aqueous process.

Typical substrates include polyester, nylon, glass, and Kevlar. While imparting electrical conductivity and a dark color to the substrates, the coating process barely affects the strength, drape, flexibility, and porosity of the starting substrates. Fabrics are tailor-made for desired resistance, thickness, porosity, surface area, flame resistance, etc.

In some embodiments, the first layer 102 and/or second layer 104 may include thin sheets of metal or metal alloy. Suitable metals need to be highly conductive, relatively lightweight, flexible, and malleable, so it may be used in the form of thin sheets. Conductive metals or metal alloys with similar properties to aluminum or copper are suitable.

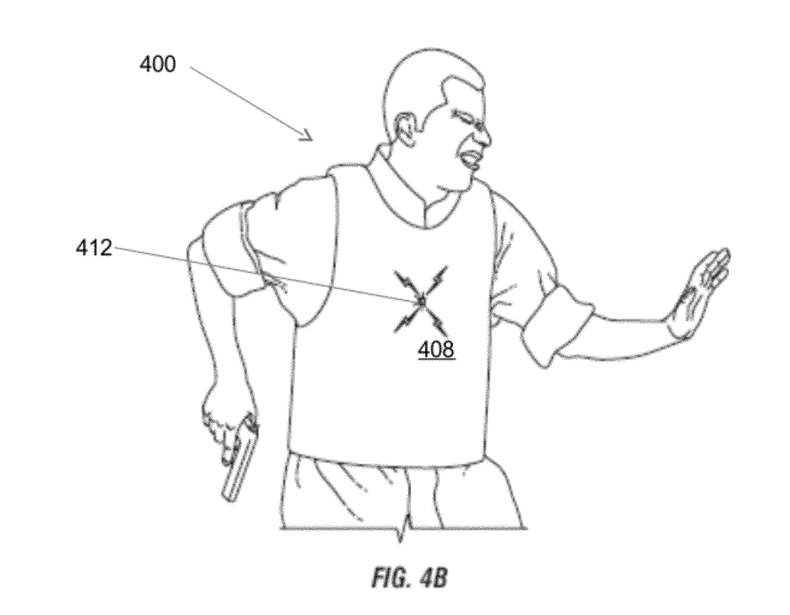

Referring briefly to FIGS. 4A and 4B, a user configured with a trauma detection system, and an impacted trauma detection system, respectively, according to embodiments disclosed herein, is shown. In operation, the trauma detection system 400 may include an electrical circuit that may be completed as the external conductive element penetrates the first layer, the insulator medium, and the second layer (not shown). Current may thus freely flow from a power source, and through the conducting materials, which may then power a transmitter device to transmit a signal.

It is not necessary that external conductive member fully penetrate the second layer. For example, the circuit may be completed, activating the transmitter device, in a scenario when the external conductive member fully penetrates the first layer and the insulator medium, but is stopped by the second layer.

The transmitter device may include any number of electronic devices that may produce a signal or wave. When activated, the device may send out a specific signal to be detected by, for example, a remote receiver, which may then inform others that trauma may have been sustained by the wearer of a detection system 400. A receiver may be functionally incorporated into any communication device used by law enforcement agents. These communication devices may be stationary or mobile, located on the law enforcement agent or in the agent's vehicle.

In some aspects, the trauma detection system may use thin sheets of electrically conductive metal or metal alloy as the first and second layers. In other aspects, the trauma detection system which may be incorporated into outerwear not necessarily designed to protect a wearer against projectile weapons. For example, military and law enforcement agents do not always wear bullet proof vests, but it is just as desirable to alert others if they experience trauma. Thus, a jacket, for example, may incorporate a trauma detection system in a similar fashion as a bullet proof vest.

Referring again to FIGS. 1A, the conductive materials particularly suitable for use in particular embodiments generally have a low electrical resistivity. Because the trauma detection system 100 may be electrically powered, it may be useful to consider that the voltage and capacity of the desired power source 110 may depend upon power requirements of the transmitter device 116 and the electrical resistance of the whole system 100. The power source 110 may be configured to produce sufficient voltage to overcome any loses incurred by the resistance of the conductive layers 102 & 104 and also power the transmitter device 116. For example, the first layer 102 and second layer 104 may incur a significant voltage drop, but the power source 110 may still provide sufficient voltage to operate the transmitter device 116. Typically, lower layer 102 & 104 resistivity values may be useful because they may translate to lower voltage output requirements form the power source 110.

As mentioned, the intermediary layer 106 may be constructed from a number of electrically non-conductive materials. For example, textiles of natural or synthetic fibers are suitable. Other materials may include natural or synthetic rubber-like polymers, as well as most plastics. Typical examples include: cotton, polyester, and nylon fabrics, rubber, polyurethane, neoprene, polyethylene, and polypropylene. The intermediary layer 106 may be configured in such a manner that it acts as a barrier to, and completely separates, the first layer 102 and the second layer 104. In an embodiment, the insulator medium 106 may be disposed in such a way that direct physical contact between the first layer 102 and the second layer 104 may be prevented.

The transmitter device comprises of any number of electronic devices which with the aid of an antenna, produces radio waves. When activated, the device may send out a specific signal to be detected by, for example, a remote receiver, which may then inform others that trauma may have been sustained by the wearer of a detection system. A receiver may be functionally incorporated into any communication device used by law enforcement agents. These communication devices may be stationary or mobile, located on the law enforcement agent or in the agent's vehicle.

In another embodiment, the transmitter device may be programmed to send out a signal containing additional information, such as GPS coordinates. The information sent may include vitals information such as, for example, user name, weight, height, allergies, impact area, impact type, impact speed, and location of impact. Software may be provided that automatically prioritizes wounded agent for aid.

Embodiments disclosed herein may provide for a passive detection system, meaning that energy is only used in an “on demand” basis. First, the transmitter device 116 needs to be configured to “normally on” or transmitting setting. Consequently, when power is supplied to the transmitter device 116, it may automatically send out a signal to a receiver at the remote location (not shown). Therefore, instead of pushing the button to transmit a signal, when the first and second layers 102 & 104 become electrically connected, the electrical circuit is completed 102, powering the transmitter device 116, which then sends out a signal. The advantage of such configuration is that the system will not use energy from the power source 110 unless the circuit is completed 102. Such configuration may preserve battery life for use when it is needed the most. Although, the battery should be changed at regular intervals, much like a smoke detectors batteries should be replaced annually.

In a correctional facility an alarm may be a practical embodiment of the detection system. For example, upon activation, the alarm may include, for example, a sound or warning configured to notify other correctional officers in the immediate area that an attack or trauma has occurred.

The power source 110 may be a battery, which may be primary or secondary type, with the output voltage to be determined by the transmitter device 116 and the inertia switch 118 power requirements as well as the combined resistance of the first and second layers 102 & 104. The power source 110 may be incorporated into the outerwear in such a fashion as to allow for an easy charging or periodic replacement.

In an embodiment, the layers 102 & 104 act as a functional switch for the transmitter or alarm. As such, during normal operating conditions the “switch” is in the open position 101. Once the body wear apparatus is penetrated by a metal object, such as a bullet or a knife, the circuit is completed and the switch is then in a “closed” position 103.

The “circuit” 108 associated with the system 100 may be closed 103 upon a connection between the first layer 102 and the second layer 104. For example, a conducting object 112, such as a knife or a bullet, may penetrate or otherwise pierce at least the first layer 102 and the medium layer 106. At any instant when the conducting object 112 contacts one or more of the layers 104, a current path 113 may be completed, and current may flow via a path of least resistance (e.g., negative terminal to positive terminal) via the connection.

Referring now to FIG. 1B, a cross-sectional view of a trauma detection system configured with an electrical circuit completed by an external conductive element, according to embodiments disclosed herein, is shown. Specifically, the electrical circuit is completed as the external conductive element penetrates the first layer, the insulator medium, and the second layer. As this happens, the electrical circuit comprising the trauma detection system is completed by the external conductive element. Current originating from one terminal of the electrical power source passes through the first layer, the external conductive element, the second layer, through the transmitter device, and into the other terminal of the electrical power source. As the current powers the transmitter device, an electronic signal is sent to a receiver placed in another location.

It is not necessary that external conductive member fully penetrate the second layer. The circuit may be completed, activating the transmitter device, in a scenario when the external conductive member fully penetrates the first layer and the insulator medium, but is stopped by the second layer.

Referring now to FIG. 1C, a cross-sectional view of a trauma detection system configured with an electrical circuit completed by deforming multiple layers according to embodiments disclosed herein, is shown. As an external member impacts the first layer, it physically compresses and then penetrates it. As it is penetrated, the first layer is deformed and stretched into and through the insulator medium, causing it to make contact with the second layer. As this happens, the electrical circuit comprising the trauma detection system is completed allowing current flow, activating the transmitter device.

As previously mentioned in general, one embodiment comprises of the trauma detection system incorporated into a bullet-proof vest. It requires for coating of two or more Kevlar or other protective layers already incorporated into the vest with a electrically conductive material. Thus, first and second layers may not be additional components incorporated into a vest, but part of the original vest design, thus making a less complicated assembly procedure and reducing chances for failure and false alarms. Other benefit of this design is the minimal additional weight which it adds to the total weight of the vest. The power source and the transmitter may be the main sources of additional weight to the vest. The insulator medium may be made from one or more Kevlar or other protective layers already incorporated into the vest, but which are not electrically conductive or coated with electrically conductive material. The insulator medium may be positioned between the first and second layer. In an embodiment, the insulator medium may completely separate the first layer and the second layer.

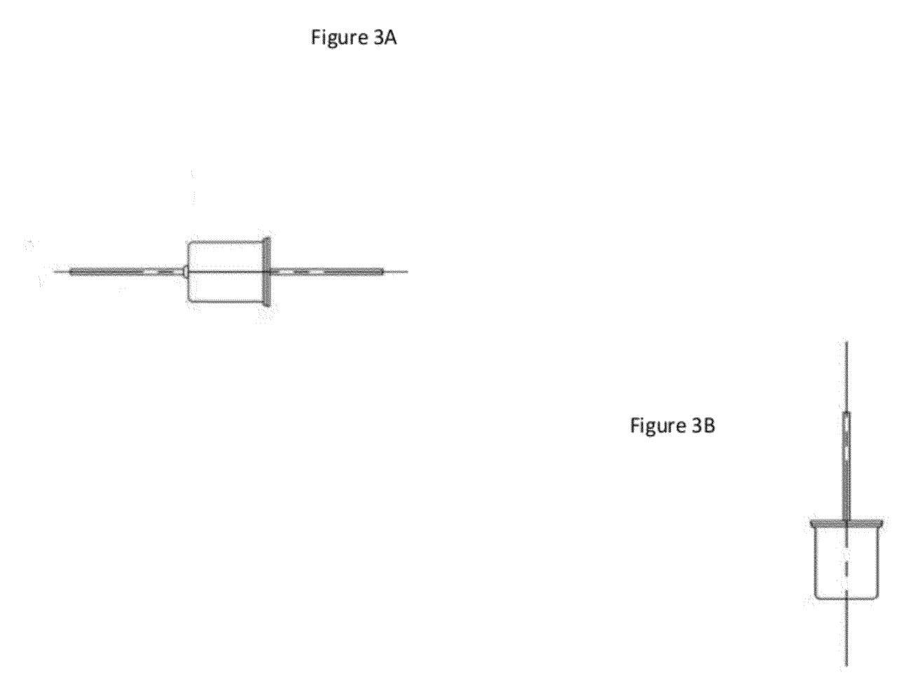

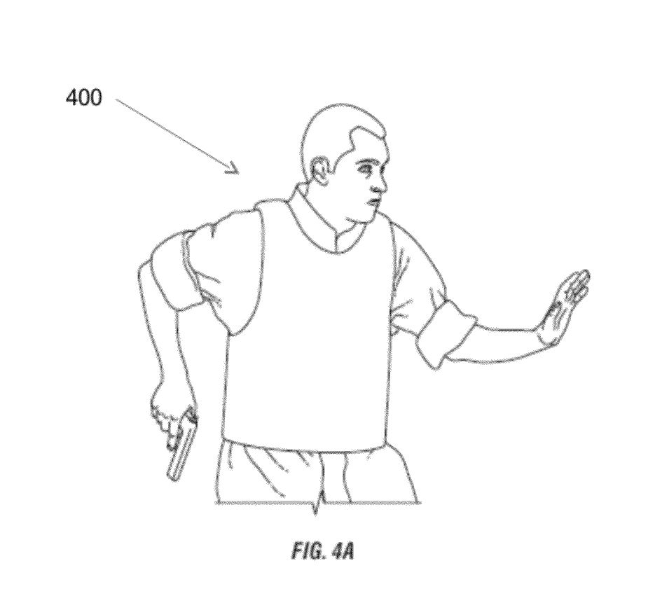

Trauma detection system may also include the inertial switch 118, which may add additional safety features to the trauma detection system. FIGS. 3A and 3B show various schematic views of an inertial position switch usable with a trauma detection system, in accordance with embodiments of the present disclosure. The switch 118 may thus be configured to provide the system 100 and/or apparatus 105 with the ability to sense or detect, for example, automobile crashes, impacts caused by falls, direct impacts with automobiles, or other comparable sudden changes in velocity. The switch may be set to be normally open state, meaning no electrical current will pass through it in its inactive or default state. Upon being subjected to a preset acceleration, the switch may close, allowing current to flow through it, as well as the transmitter device 116 thus powering it. Essentially, the inertial switch 118 may be another way to activate the transmitter device 116, allowing the system 100 to sense different sources of trauma.

The inertia switch 118 may be a separate device connected to the circuit, or may be part of a device that includes both the transmitter 116 and switch 118. No power is required for operation making them an excellent choice for battery powered applications. In an embodiment, the switch and transmitter may be in connected in series, while in other embodiments the switch and transmitter may be in connected in parallel.

In other aspects, the inertia switch 118 may be a PCB series inertia switch. These types of switches are readily usable in instances where size of the switch may be a critical factor. The switch may be a damped or undamped model and may incorporate single or multi-axis detection. Solid wire leads, insulated wire leads, standard terminals that may be configured to work with AC or DC current.

Referring now to FIG. 2, a cross-sectional view of a layered trauma detection system as part of a body wear apparatus configured with an electrical circuit according to embodiments disclosed herein, is shown. The trauma detection system 200 may include one or more layers 202, 204, 206. In some embodiments, the layer 206 may be an intermediary layer configured to keep the layers 202 & 204 from direct contact with each other.

The first layer 202 may be an outer layer that is conductive. In one aspect of operation or use, the layer 202 may be conductive, but not electrified. In this manner, the layer 102 may be an effective “negative” terminal. The intermediary layer 206 may be an insulating layer configured to prevent current flow through the layer(s) 202, 204. The second layer 204 may be configured with penetration-resistant material, such as KEVLAR, that may be further “treated” to be conductive. In an embodiment, layer 204 may be electrified/energized, and in effect, functions as a “positive” terminal.

The trauma detecting system may include a body wear apparatus 200a configured with the first layer 202 as an outer conductive layer. The intermediary layer 206 may be disposed or otherwise positioned proximate to the outer conductive layer 202, and the intermediary (e.g., middle, medium, inbetween, etc.) layer may be made from an insulating material configured to prevent current flow to the outer layer 202.

The apparatus 200a may also include the layer 204 configured as an inner conductive layer made from a penetration-resistant material. In an embodiment, the inner layer 204 may be configured with a conductive coating treatment, and wherein the inner conductive layer 204 may be connected to an energized power source (110, FIG. 1A).

Although not shown here, the apparatus 200a may be operatively fitted or connected with a transmitter configured to transmit a signal when current flows from the energized power source to the outer conductive layer.

As such, the electrical circuit of the body wear 200a may be completed upon an electrical connection between the outer conductive layer 202 and the inner conductive layer 204. In an embodiment, the electrical circuit is completed by an object. The object may be, for example, a penetrating object that penetrates the outer conductive layer and the medium layer, such as a bullet, a knife, an arrow, etc.

As shown in FIG. 2, the trauma detecting body wear apparatus 200a may include a second outer conductive layer 202a. In addition, there may be a plurality of additional intermediary layers 206a. Each of the plurality of medium layers may be made from insulating material configured to prevent current flow flowing between various layers.

There may be a plurality of inner conductive layers 204a. Any of the plurality of inner conductive layers 204a may be made from a penetration-resistant material. In addition, any of the plurality of inner conductive layers 204 may be configured with a conductive coating treatment, like layers previously described.

In some aspects, the trauma detection system may use thin sheets of electrically conductive metal or metal alloy as the first and second layers. In other aspects, the trauma detection system which may be incorporated into outerwear not necessarily designed to protect a wearer against projectile weapons. For example, military and law enforcement agents do not always wear bullet proof vests, but it is just as desirable to alert others if they experience trauma. Thus, a jacket, for example, may incorporate a trauma detection system in a similar fashion as a bullet proof vest.

In this manner, two layers of fabric may be disposed within the jacket, whereby each may be coated with electrically conductive material and be fully separated by another layer of fabric, acting as the insulator layer. Depending on the style of the jacket, these layers may be continuous, spanning from the front left side of the jacket, continuing around the back, to the front right side. The jacket system may thus include three sets of layers, one set on the front left side, one on the front right side, and one in the back.

Even without bullet-proofing in clothing, impact sensing clothing may beneficially play a vital role in saving the lives of soldiers or law enforcement agents. This technology and all its advantages may be incorporated into clothing suitable for almost any situation these individuals are engaged in. Just as in the case of a bullet proof vest, the instant an objects penetrates impact-sensing clothing, a signal may be sent to, for example, a medical center, ground commander, nearby soldiers, medical vehicles. The information sent may include vitals information such as, for example, the soldier's name, weight, height, allergies, impact area, impact type, impact speed, and location of impact. Software may be provided that automatically prioritizes wounded soldiers for pickup/aid.

Advantageously, embodiments disclosed herein my readily save the lives of law enforcement officers, corrections officers, military personnel, as well as other persons. Not only may persons wearing the vest benefit, but any persons having to investigate a nonresponsive officer may also benefit by being forwarned or altered to dangers prior to arriving on scene.

Of other benefits, the body wear apparatus may be readily incorporated into pre-existing infrastructures, such as already fabricated vests and body wear. As such, embodiments disclosed herein beneficially have the ability to provide an upgrade/retrofit item.

Embodiments disclosed herein may provide for conductive body armor that is portable, comfortable, reliable, and readily detects various traumas, such as impacts or penetration by foreign objects. The wearer may notice a minimal increase in weight, allowing for preservation of strength and energy for longer periods of time. The impairment of movement and flexibility will also be reduced, as compared to other trauma detection system designs. Beneficially, the simplicity of design may result in increase in reliability, as smaller number of components translates to smaller number of malfunctions. Of significant benefit is the system's ability to sense a multitude of traumas, as the signal triggering is independent of the type, shape, or speed of the weapon.

While the present disclosure has been described with respect to a limited number of embodiments, those skilled in the art, having benefit of the present disclosure will appreciate that other embodiments may be devised which do not depart from the scope of the disclosure described herein. Accordingly, the scope of the disclosure should be limited only by the claims appended hereto.

1. An trauma detection system comprising:
a section of body armor further comprising:
a first layer;
a second layer disposed proximate to the first layer;
an insulator medium positioned between the first layer and the second layer;
a transmitter device; and
a power source in powered connection with the transmitter device, and also configured to supply power to the transmitter device,
wherein the first layer is operatively connected to the power source,
wherein the second layer is operatively connected to the transmitter device,
wherein the transmitter device is configured to transmit a trauma signal when the first layer and the insulating medium are penetrated by an external conductive element that also at least partially contacts the second layer.

2. The trauma detection system of claim 1, wherein the first layer comprises a first portion and the second layer comprises a second portion, and wherein the first portion and the second portion are oriented in a parallel manner with respect to each other.

3. The trauma detection system of claim 2, wherein the insulator medium comprises non-conductive material, and wherein at least part of the insulator medium is oriented generally parallel with, and entirely between, the first portion and the second portion.

4. The trauma detection system of claim 3, wherein the power source comprises a battery.

5. The trauma detection system of claim 3, wherein the power source comprises an electrical power source, wherein the electrical power source comprises a first terminal in electrical connection with the first layer, and wherein the electrical power source comprises a second terminal in electrical connection with the transmitter device.

6. The trauma detection system of claim 4, wherein the first portion and the second portion each comprise an electrically conductive material.

7. The trauma detection system of claim 4, the system further comprising an inertial switch, wherein the inertial switch is configured to transfer electrical power to the transmitter device when the inertial switch is activated.

8. A trauma detecting body wear apparatus, the apparatus comprising:
an outer conductive layer;
a medium layer proximate to the outer conductive layer, wherein the medium layer comprises an insulating material configured to prevent current flow to the outer layer;
an inner conductive layer comprising a penetration-resistant material, wherein the inner layer is configured with a conductive coating treatment, and wherein the inner conductive layer is connected to an energized power source;
a transmitter configured to transmit a signal when current flows from the energized power source to the outer conductive layer.

9. The trauma detecting body wear apparatus of claim 7, wherein an electrical circuit is completed upon an electrical connection between the outer conductive layer and the inner conductive layer.

10. The trauma detecting body wear apparatus of claim 8, wherein the electrical circuit is completed by an object.

11. The trauma detecting body wear apparatus of claim 9, wherein the object comprises a penetrating object that penetrates the outer conductive layer and the medium layer.

12. The trauma detecting body wear apparatus of claim 10, wherein the medium layer comprises a plastic

13. The trauma detecting body wear apparatus of claim 10, the apparatus comprising:
a second outer conductive layer;
a plurality of medium layers, wherein each of the plurality of medium layers comprise an insulating material configured to prevent current flow therethrough;
a plurality of inner conductive layers, each of the plurality of inner conductive layers comprising a penetration-resistant material, and wherein each of the plurality of inner conductive layers is configured with a conductive coating treatment.

14. The trauma detecting body wear apparatus of claim 9, wherein the object comprises a bullet, a knife, an arrow, and combinations thereof.

15. A method for detecting trauma, comprising the steps of:
using a section of body armor, the section of body armor comprising:
a first layer;
a second layer disposed proximate to the first layer;
an insulator medium positioned between the first layer and the second layer;
a transmitter device; and
a power source in powered connection with the transmitter device, and also configured to supply power to the transmitter device, transmitting a signal that pertains to a detected trauma by contacting the first layer with the second layer.

16. The method of claim 15, the method further comprising having first responders respond to the transmitted signal.

17. The method of claim 16, wherein the first layer and the second layer are configured to contact each other upon at least one of an impact of the first layer, a penetration of the first layer, and combinations thereof.

18. The method of claim 17, wherein the power source comprises an electrical power source, wherein the electrical power source comprises a first terminal in electrical connection with the first layer, and wherein the electrical power source comprises a second terminal in electrical connection with the transmitter device.

19. The method of claim 15, wherein the first layer and the second layer are configured to contact each other upon at least one of an impact of the first layer, a penetration of the first layer, and combinations thereof.
